(19) United States
(12) Patent Application Publication
(10) Pub. No.: US 2021/0175138 A1
(43) Pub. Date: Jun. 10, 2021

(54) Semiconductors Having Die Pads with Environmental Protection and Process of Making Semiconductors Having Die Pads with Environmental Protection

(71) Applicant: Cree, Inc., Durham, NC (US)

(72) Inventor: Kyoung-Keun Lee, Cary, NC (US)

(21) Appl. No.: 16/704,644

(22) Filed: Dec. 5, 2019

(51) Int. Cl. H01L 23/31; H01L 21/56

(52) U.S. Cl. CPC H01L 23/3121; H01L 21/56; H01L 23/3135

(57) ABSTRACT

A process of forming a device with a pad structure having environmental protection includes providing a semiconductor body portion, arranging a pad on the semiconductor body portion, providing at least one environment encapsulation portion at least partially on the pad, arranging a supplemental pad on the pad, and arranging the supplemental pad to include side surfaces that extend vertically above the at least one environment encapsulation portion. A device having a pad structure having environmental protection is also disclosed.

### FIELD OF THE DISCLOSURE

The disclosure relates to semiconductors having die pads with environmental protection. The disclosure further relates to a process of making semiconductors having die pads with environmental protection.

### BACKGROUND OF THE DISCLOSURE

Semiconductor devices are often used in systems that are exposed to a variety of harsh environmental conditions. For example, the semiconductor devices are typically exposed to extreme temperature ranges, humidity ranges, and/or a host of other environmental conditions that may negatively impact the semiconductor devices. The other environmental conditions may include environments having water, oxygen, hydrogen, and/or the like. Moreover, the semiconductor devices are often required to operate at or near their rated currents and voltages over extended periods of time. However, operating in extreme environmental conditions and/or at elevated levels often leads to failure of the devices and/or deterioration in semiconductor performance.

In this regard, surface passivation techniques are typically utilized to encapsulate sensitive surfaces of the semiconductor devices in an effort to reduce the deteriorating affects associated with being exposed to extreme environmental conditions, operating at elevated levels, and/or the like. While current passivation techniques have proven to be beneficial, these techniques have still been found to be insufficient.

For example, humidity migration resistance is one challenge impacting semiconductor components that reduces operating life. In this regard, humidity migration resistance is typically enhanced by utilizing passivation films and/or environment encapsulation (EE) on a top of a semiconductor die. Among the humidity failure mechanisms, insufficiently optimized wire bonding processes can typically be a significant failure of humidity migration resistance.

Accordingly, there is a need for more effective techniques in order to improve device reliability under extreme environmental conditions and elevated operating levels.

### SUMMARY OF THE DISCLOSURE

One general aspect includes a device configured with a pad structure having environmental protection, the device including: a semiconductor body portion, at least one environment encapsulation portion, a supplemental pad, the pad being arranged on the semiconductor body portion, and the supplemental pad being arranged on the pad. The device also includes where the supplemental pad includes side surfaces that extend vertically above the at least one environment encapsulation portion.

One general aspect includes a process of forming a device with a pad structure having environmental protection, the process including: providing a semiconductor body portion, arranging a pad on the semiconductor body portion, providing at least one environment encapsulation portion at least partially on the pad, arranging a supplemental pad on the pad, and arranging the supplemental pad to include side surfaces that extend vertically above the at least one environment encapsulation portion.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 shows a cross-sectional view of a pad structure for a device according to the disclosure.

FIG. 2 shows a cross-sectional view of a pad structure for a device according to another aspect of the disclosure.

FIG. 3 shows a cross-sectional view of a pad structure for a device illustrating internal forces according to FIG. 1.

FIG. 4 shows a cross-sectional view of a pad structure for a device according to FIG. 1.

FIG. 5 shows a cross-sectional view of a pad structure for a device according to another aspect of the disclosure.

FIG. 6 shows a cross-sectional view of a pad structure for a device according to another aspect of the disclosure.

FIG. 7 shows a process of making a pad structure according to the disclosure.

FIG. 8 shows a cross-sectional view of one aspect of a transistor implementing a pad structure according to the disclosure.

FIG. 9 shows a cross-sectional view of one aspect of a transistor implementing a pad structure according to the disclosure.

FIG. 10 shows a cross-sectional view of one aspect of a transistor implementing a pad structure according to the disclosure.

FIG. 11 shows a process of making a transistor according to the disclosure.

FIG. 12 illustrates top view of a device having a pad structure.

FIG. 13 illustrates cross-sectional view of a device having a pad structure according to FIG. 12.

FIG. 14 illustrates a view of a device having a pad structure according to FIG. 12 observed by a Nomarksi optical microscope.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

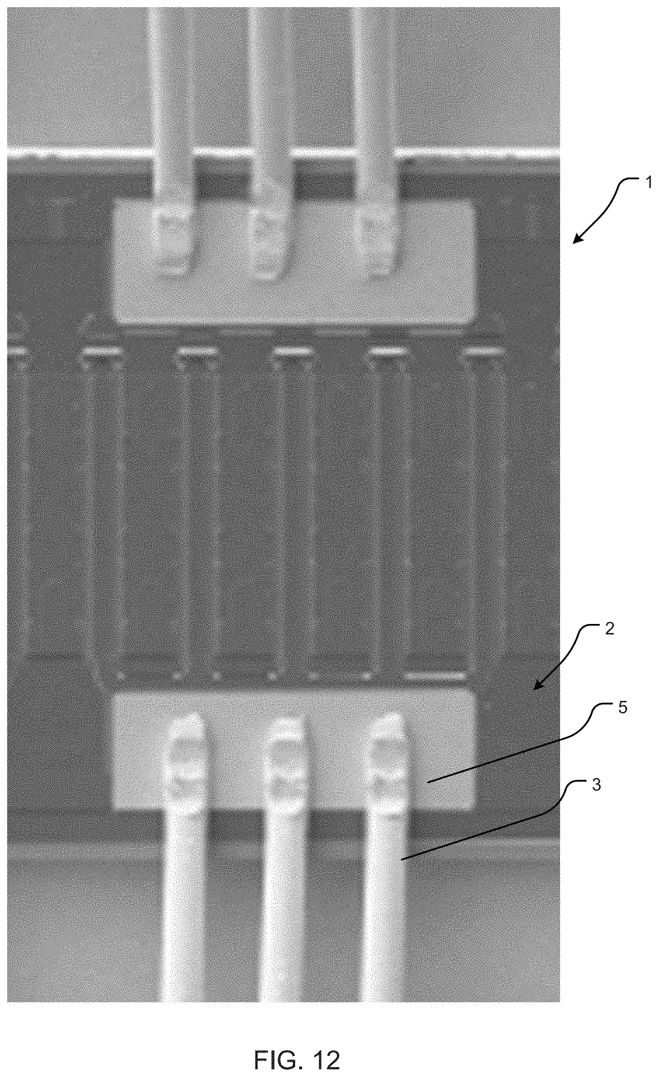

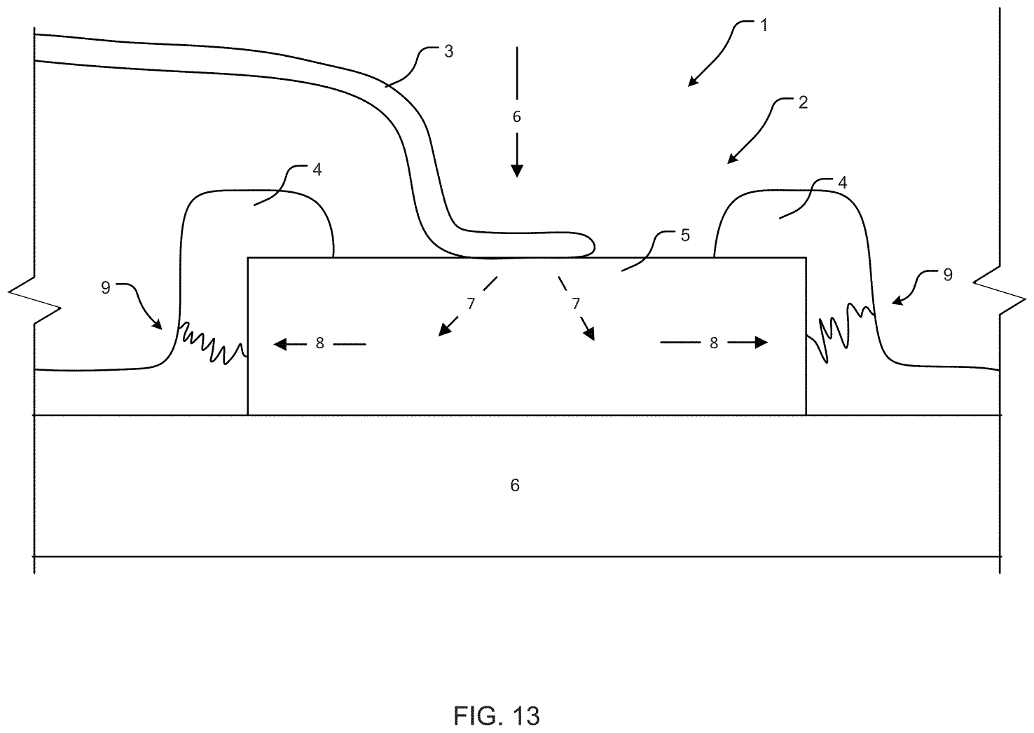

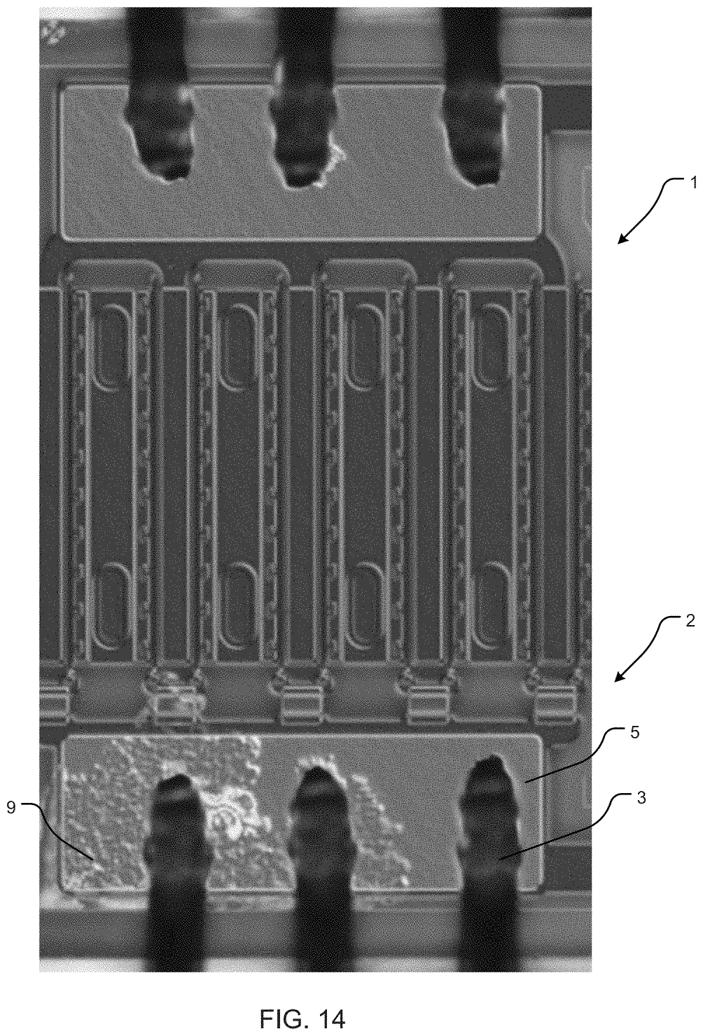

With reference to FIG. 12, a device 1 is illustrated and the device 1 may include a pad structure 2. The pad structure 2 may include a pad 5 for attachment of a wire 3. With reference to FIG. 13, the device 1 may further include a EE film 4. The wire bonding of the wire 3 to the pad 5 is typically a process to attach the wire 3 by applying sonicated force 6 to the pad 5 of the device 1 for electrical connection as shown in FIG. 12 and FIG. 13. However, unoptimized previous wire bonding processes have caused the EE film 4 in some cases to form sidewall cracks 9 as shown in FIG. 13. In particular, the sonicated force 6 typically travels through the pad 5 as illustrated by arrow 7 and arrow 8 to the EE film 4 that applies a force on and causes stress on the EE film 4 that in some cases forms the sidewall cracks 9 as shown in FIG. 13. FIG. 14 further shows the device 1 observed by a Nomarksi optical microscope illustrating the sidewall cracks 9 that may result in a degraded device life and/or deterioration in semiconductor performance.

Statistically, even optimized wire bonding processes still result in device failure and/or device loss because of manufacturing uncertainties. These manufacturing uncertainties may include touch down issues, which apply more force to a pad for example due to a bent seeding wire.

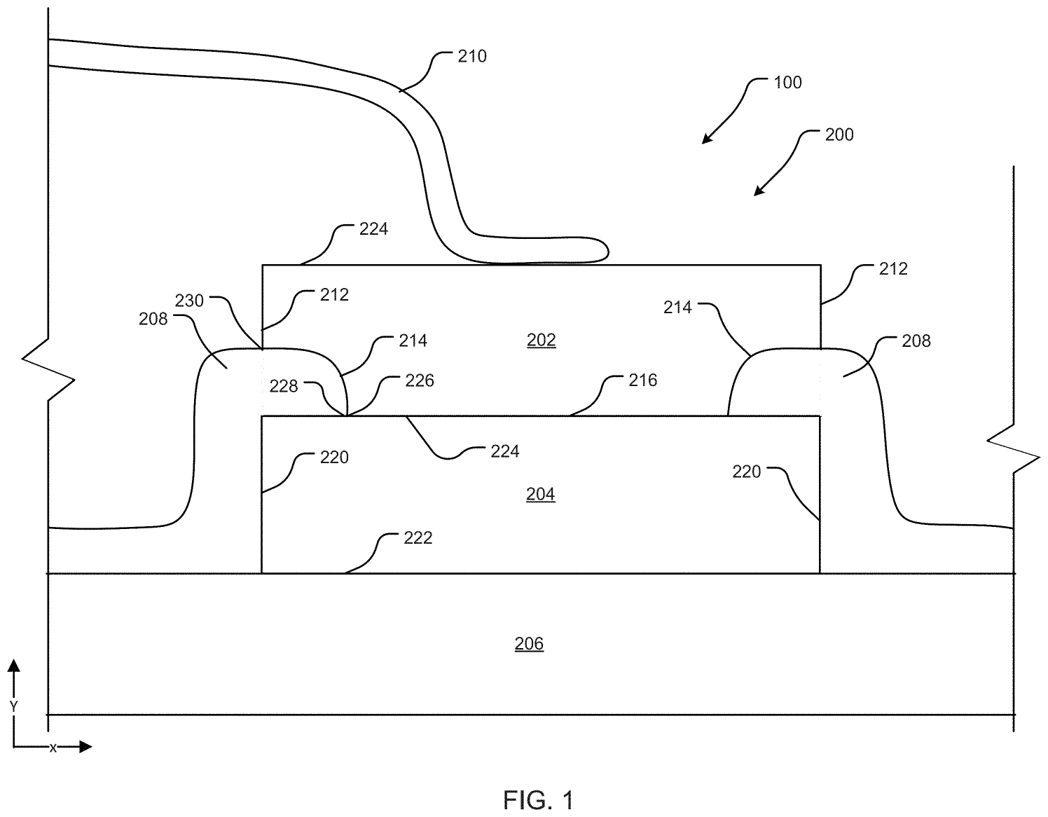

FIG. 1 shows a cross-sectional view of a pad structure for a device according to the disclosure.

In particular, FIG. 1 illustrates a device 100 that may include a pad structure 200. The pad structure may include a pad 204, a supplemental pad 202, and at least one environment encapsulation (EE) portion 208. Additionally, the pad structure 200 may be configured to connect to a bonding wire 210 and a semiconductor body portion 206.

In one aspect, the pad 204 may be on the semiconductor body portion 206. In one aspect, the pad 204 may be directly on the semiconductor body portion 206. In one aspect, the pad 204 may be connected to the semiconductor body portion 206. In one aspect, the pad 204 may be directly connected to the semiconductor body portion 206. In one aspect, there may be intervening layers or structures between the pad 204 and the semiconductor body portion 206.

In one aspect, the supplemental pad 202 may be on the pad 204. In one aspect, the supplemental pad 202 may be directly on the pad 204. In one aspect, the supplemental pad 202 may be connected to the pad 204. In one aspect, the supplemental pad 202 may be directly connected to the pad 204. In one aspect, there may be intervening layers or structures between the supplemental pad 202 and the pad 204.

In one aspect, the pad 204 may be formed from a metal such as aluminum (Al), gold (Au), silver (Ag), platinum (Pt), titanium (Ti), silicon (Si), nickel (Ni), copper (Cu), combinations thereof, and/or the like. Additionally, the pad 204 may be formed of multiple layers and/or one or more overlayers of metal such as aluminum (Al), gold (Au), silver (Ag), platinum (Pt), titanium (Ti), silicon (Si), nickel (Ni), copper (Cu), combinations thereof, and/or the like. The pad 204 may be attached to the semiconductor body portion 206 along a lower surface 222 of the pad 204. Additionally, the pad 204 may include a top surface 224 and side surfaces 220.

In one aspect, the at least one EE portion 208 may partially contact and cover the side surfaces 220 of the pad 204. In one aspect, the at least one EE portion 208 may contact and fully cover the side surfaces 220 of the pad 204.

In one aspect, the at least one EE portion 208 may partially contact and partially cover the top surface 224 of the pad 204. In one aspect, the at least one EE portion 208 may partially contact and partially cover the top surface 224 of the pad 204 and leave a central portion of the top surface 224 free of the at least one EE portion 208.

In one aspect, the supplemental pad 202 may be formed from a metal such as aluminum (Al), gold (Au), silver (Ag), platinum (Pt), titanium (Ti), silicon (Si), nickel (Ni), copper (Cu), combinations thereof, and/or the like. Additionally, the supplemental pad 202 may be formed of multiple layers and/or one or more overlayers of metal such as aluminum (Al), gold (Au), silver (Ag), platinum (Pt), titanium (Ti), silicon (Si), nickel (Ni), copper (Cu), combinations thereof, and/or the like. In one aspect, the material of the supplemental pad 202 may be the same as the material of the pad 204. In one aspect, the material of the supplemental pad 202 and the material of the pad 204 may be different. In one aspect, the supplemental pad 202 may include a bottom surface 216 configured to contact the top surface 224 of the pad 204. In one aspect, the bottom surface 216 of the supplemental pad 202 may contact the central portion of the top surface 224, which may be free of the at least one EE portion 208.

In one aspect, the supplemental pad 202 may include side surfaces 212. In one aspect, the side surfaces 212 may include a surface that is generally perpendicular to the bottom surface 216 and/or a surface that may be generally parallel to a y-axis as illustrated. In one aspect, the side surfaces 212 may be partially free of the at least one EE portion 208. In one aspect, the side surfaces 212 may be free of the at least one EE portion 208. In one aspect, the side surfaces 212 may extend vertically from the at least one EE portion 208. In one aspect, the side surfaces 212 may extend generally vertically along the y-axis from the at least one EE portion 208 as illustrated. In this regard, generally may be defined to be within 0°-15°, 0°-2°, 2°-4°, 4°-6°, 6°-8°, 8°-10°, 10°-12°, or 12°-15°.

In one aspect, the supplemental pad 202 may include a top surface 224. In one aspect, the top surface 224 may be generally parallel to the bottom surface 216. In one aspect, the top surface 224 may be generally parallel to an x-axis as illustrated. In one aspect, the top surface 224 may be free of the at least one EE portion 208.

In one aspect, the supplemental pad 202 may include lower side surfaces 214. In one aspect, the lower side surfaces 214 may connect to the bottom surface 216. In one aspect, the lower side surfaces 214 may connect to the side surfaces 212. In one aspect, the lower side surfaces 214 may connect to the bottom surface 216 and may connect to the side surfaces 212. In one aspect, the lower side surfaces 214 may contact the at least one EE portion 208.

In one aspect, the lower side surfaces 214 may connect to the bottom surface 216. In one aspect, the lower side surfaces 214 may connect to the bottom surface 216 at an inflection point 226. The inflection point 226 may be a corner, an edge, a curved corner, a curved edge, a lip, an interface, and the like.

In one aspect, the lower side surfaces 214 may connect to the side surfaces 212. In one aspect, the lower side surfaces 214 may connect to the side surfaces 212 at an inflection point 230. The inflection point 230 may be a corner, an edge, a curved corner, a curved edge, a lip, an interface, and the like.

In one aspect, the at least one EE portion 208 may include end portions 228. The end portions 228 may be a terminating point, a corner, an edge, a curved corner, a curved edge, a lip, an interface, and the like. In one aspect, the inflection point 226 may be adjacent the end portions 228. In one aspect, the inflection point 226 may be on the end portions 228. In one aspect, portions of the supplemental pad 202 may be arranged above the at least one EE portion 208. In one aspect, portions of the supplemental pad 202 may be arranged above the end portions 228. In one aspect, the side surfaces 212 may be arranged above the at least one EE portion 208. In one aspect, the side surfaces 212 may be arranged above the end portions 228. In one aspect, the top surface 224 may be arranged above the at least one EE portion 208. In one aspect, the top surface 224 may be arranged above the end portions 228. It should be noted that the term above is meant to describe an orientation of a structure vertically above another structure with respect to the y-axis as illustrated and should not be limited or construed to being on the same axis. In one aspect, the side surfaces 212 may be arranged vertically above the at least one EE portion 208 along a vertical axis and/or the y-axis. In one aspect, the side surfaces 212 may be arranged vertically directly above the at least one EE portion 208 along a same vertical axis and/or the y-axis. In one aspect, the end portions 228, the inflection point 226, and the bottom surface 216 of the supplemental pad 202 may be arranged along a same horizontal axis and/or the x-axis.

As further described below, the at least one EE portion 208 may comprise a single layer, a plurality of layers having a same type of material, a plurality of layers having different types of material, combinations of material layers, and the like. Additionally, as described herein the at least one EE portion 208 may comprise SiN, AlO, SiO, SiO₂, AlN, and/or the like. In one aspect, the at least one EE portion 208 may be a passivation layer that is SiN. In one aspect, the passivation layer may be deposited using a plasma enhanced chemical vapor deposition (PECVD) process and may have a thickness between about 6400 and 9600 Angstroms with a relatively high index of refraction between about 1.85 and 2.25. Alternative thickness ranges for the passivation layer may be between about 7500 and 8500 Angstroms and between about 7800 and 8200 Angstroms. An alternative index of fraction range may be between about 1.95 and 2.15. Other thickness ranges for the passivation layer and index of fraction ranges are contemplated as well. Additionally, the at least one EE portion 208 may comprise additional layers arranged below and/or above having a same type of material and/or having different types of material.

In one aspect, the at least one EE portion 208 may be a passivation layer that may be SiO₂ that may be deposited using PECVD with a thickness between about 750 and 1250 Angstroms with a relatively low index of refraction between about 1.4 and 1.6. Alternative thickness ranges for the passivation layer may be between about 800 and 1200 Angstroms and between about 900 and 1100 Angstroms. An alternative index of fraction range is between about 1.45 and 1.5. Other thickness ranges for the passivation layer and index of fraction ranges are contemplated as well. Additionally, the at least one EE portion 208 may comprise additional layers arranged below and/or above having a same type of material and/or having different types of material.

In one aspect, the at least one EE portion 208 may be a passivation layer that may be SiN. The passivation layer may be deposited using PECVD with a thickness that may be between about 2200 and 3800 Angstroms with a relatively high index of refraction between about 1.85 and 2.25. Alternative thickness ranges for the passivation layer may be between about 2400 and 3600 Angstroms and between about 2800 and 3200 Angstroms. An alternative index of fraction range is between about 1.95 and 2.15. Other thickness ranges for the passivation layer and index of fraction ranges are contemplated as well. Additionally, the at least one EE portion 208 may comprise additional layers arranged below and/or above having a same type of material and/or having different types of material.

In one aspect, an encapsulation layer may be provided over the passivation layer. The encapsulation layer may be a polyimide, organic or polymer-based scratch protectant, or the like.

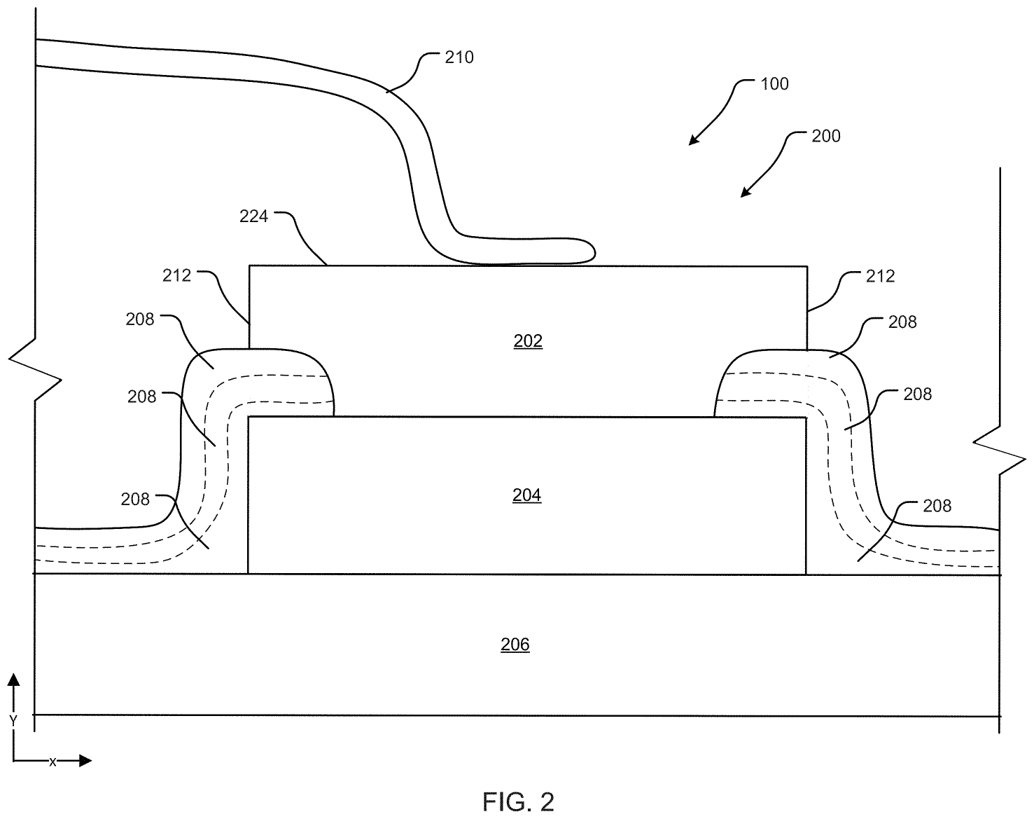

FIG. 2 shows a cross-sectional view of a pad structure for a device according to another aspect of the disclosure.

In particular, FIG. 2 illustrates the pad structure 200 which may include any one or more of the features as described herein and the at least one EE portion 208 may include multiple layers. In this regard, the at least one EE portion 208 may comprise a plurality of layers having a same type of material, a plurality of layers having different types of material, combinations of material layers, and the like. Moreover, the number of layers of the at least one EE portion 208 illustrated in FIG. 2 is merely exemplary. Any number of layers of the at least one EE portion 208 is contemplated and the number of layers may be based on an application of the device 100. In one aspect, the at least one EE portion 208 may include one or more of a first passivation layer, a second passivation layer, and a third passivation layer, which may be deposited successively in a single deposition run or multiple deposition runs using a PECVD process, atomic layer deposition (ALD) process, or like deposition process.

In one aspect, the first passivation layer is SiN, the second passivation layer is SiO₂, and the third passivation layer is SiN. In one aspect, the first passivation layer may be deposited using PECVD with a thickness that may be between about 6400 and 9600 Angstroms with a relatively high index of refraction between about 1.85 and 2.25. Alternative thickness ranges for the first passivation layer may be between about 7500 and 8500 Angstroms and between about 7800 and 8200 Angstroms. An alternative index of fraction range may be between about 1.95 and 2.15. Other thickness ranges for the first passivation layer and index of fraction ranges are contemplated as well.

The second passivation layer may be deposited using PECVD with a thickness that may be between about 750 and 1250 Angstroms with a relatively low index of refraction between about 1.4 and 1.6. Alternative thickness ranges for the second passivation layer may be between about 800 and 1200 Angstroms and between about 900 and 1100 Angstroms. An alternative index of fraction range may be between about 1.45 and 1.5. Other thickness ranges for the second passivation layer and index of fraction ranges are contemplated as well.

The third passivation layer may be deposited using PECVD with a thickness that may be between about 2200 and 3800 Angstroms with a relatively high index of refraction between about 1.85 and 2.25. Alternative thickness ranges for the third passivation layer may be between about 2400 and 3600 Angstroms and between about 2800 and 3200 Angstroms. An alternative index of fraction range is between about 1.95 and 2.15. Other thickness ranges for the third passivation layer and index of fraction ranges are contemplated as well.

In one aspect, the thickness of the first passivation layer may be greater than the thickness of the third passivation layer, which is greater than the thickness of the second passivation layer. An encapsulation layer may be provided over the third passivation layer. The encapsulation layer may be a polyimide, organic or polymer-based scratch protectant, or the like. Additionally, it should be noted that various features of the pad structure 200 may only be referenced or described with respect to one side thereof. However, the various features of the pad structure 200 may exist on multiple sides of the pad structure 200. In this regard, the pad structure 200 may include two or more sides and the various features may be arranged on each one of the multiple sides.

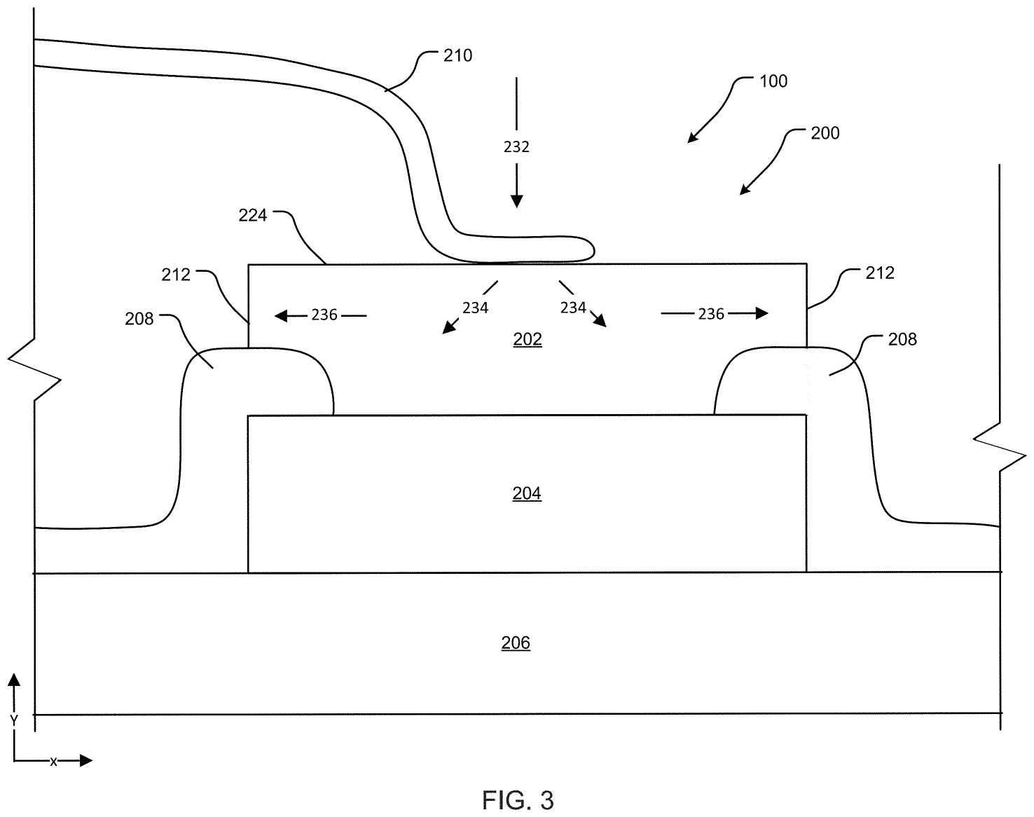

FIG. 3 shows a cross-sectional view of a pad structure for a device illustrating internal forces according to FIG. 1.

In particular, FIG. 3 illustrates internal forces and/or internal stresses and external forces experienced by the connection of the wire 210 to the supplemental pad 202. In this regard, as the wire 210 is attached to the supplemental pad 202, a force 232, such as sonicated force, may be applied to the wire 210. The force 232 may be generally applied along a y-axis and/or perpendicular to the top surface 224. The force 232 may result in forces 234 and/or internal stress within the supplemental pad 202. The forces 234 may subsequently result in forces 236 and/or internal stress within the supplemental pad 202. The forces 234 may extend generally along an x-axis as illustrated.

In one aspect, the side surfaces 212 of the supplemental pad 202 may be configured to release stress associated with the forces 236. In one aspect, the side surfaces 212 of the supplemental pad 202 may be configured to be free of the at least one EE portion 208, and the forces 236 are accordingly less likely to damage the at least one EE portion 208.

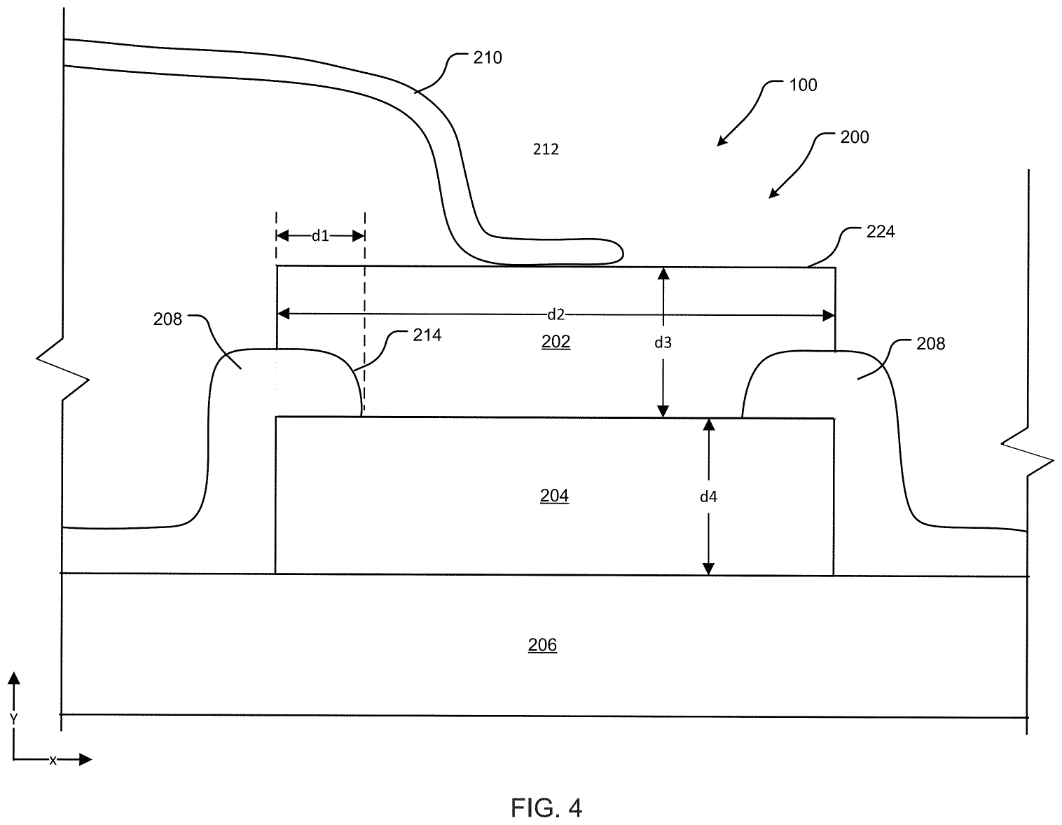

FIG. 4 shows a cross-sectional view of a pad structure for a device according to FIG. 1.

In particular, FIG. 4 illustrates exemplary dimensions of the pad structure 200. A length of the side surface 214 may be defined as a depth d1. The depth d1 may be taken along a line generally parallel to the x-axis, and/or a line generally parallel to the top surface 224. Moreover, the depth d1 may be defined as a percentage of a length or a depth d2 of the supplemental pad 202 along a line generally parallel to the x-axis, and/or a line generally parallel to the top surface 224. In aspects, the depth d1 may be 0%-30% of the depth d2, 5%-10% of the depth d2, 10%-15% of the depth d2, 15%-20% of the depth d2, 20%-25% of the depth d2, 25%-30% of the depth d2.

The thickness or the depth d3 of the supplemental pad 202 may be taken along a line generally parallel to the y-axis, and/or a line generally perpendicular to the top surface 224. Moreover, the depth d3 may be defined as a percentage of a thickness or a depth d4 of the pad 204. In aspects, the depth d3 may be 50%-200% of the depth d4, 50%-80% of the depth d4, 80%-100% of the depth d4, 90%-120% of the depth d4, 120%-160% of the depth d4, or 160%-200% of the depth d4.

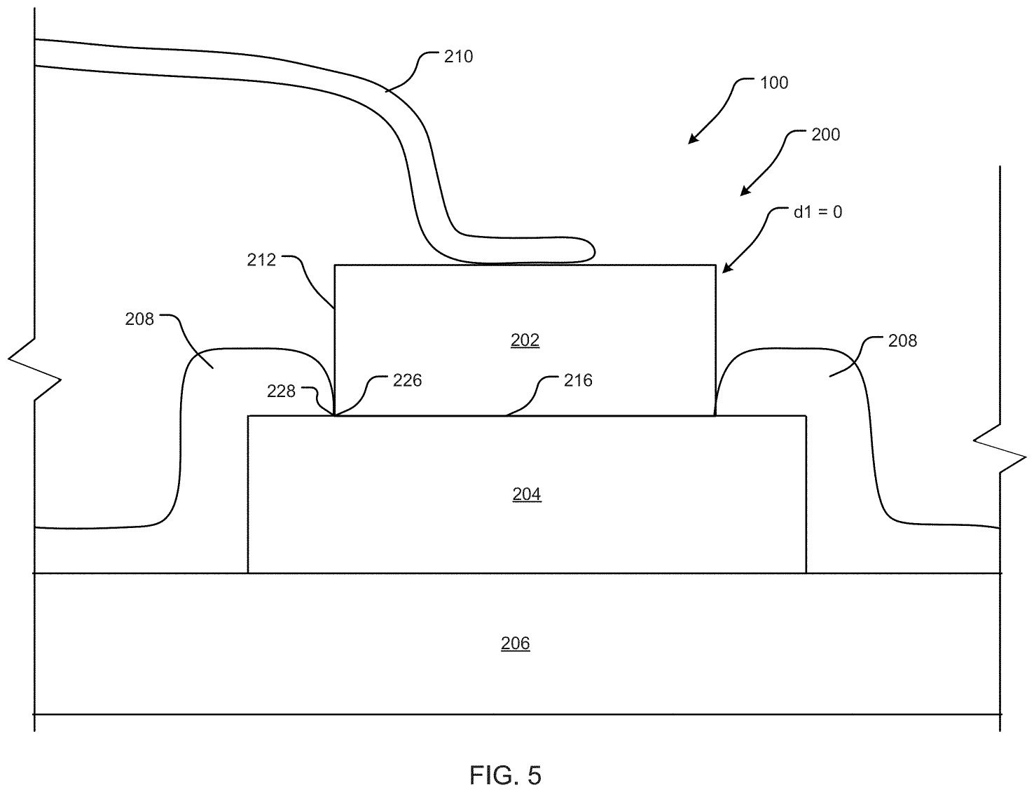

FIG. 5 shows a cross-sectional view of a pad structure for a device according to another aspect of the disclosure.

In particular, FIG. 5 illustrates the pad structure 200 which may include any one or more of the features as described herein. More specifically, the FIG. 5 aspect of the supplemental pad 202 may implement a construction without the lower side surfaces 214. Accordingly, in this aspect the depth d1 may be equal to 0.

In one aspect, the side surfaces 212 of the supplemental pad 202 may be configured to release stress associated with the forces as illustrated in FIG. 3. In one aspect, the side surfaces 212 of the supplemental pad 202 may be configured to be substantially free of the at least one EE portion 208, and the forces are accordingly less likely to damage the at least one EE portion 208. In one aspect, portions of the supplemental pad 202 may be arranged above the at least one EE portion 208. In one aspect, portions of the supplemental pad 202 may be arranged above the end portions 228. In one aspect, the side surfaces 212 may be arranged above the at least one EE portion 208. In one aspect, portions of the side surfaces 212 may be arranged above the end portions 228. In one aspect, the top surface 224 may be arranged above the at least one EE portion 208. In one aspect, the top surface 224 may be arranged above the end portions 228. In one aspect, the end portions 228 and the bottom surface 216 of the supplemental pad 202 may be arranged along a same horizontal axis and/or the x-axis. In one aspect, the side surfaces 212 may be arranged vertically above the end portions 228 along a vertical axis and/or the y-axis. In one aspect, the side surfaces 212 may be arranged vertically directly above the end portions 228 along a same vertical axis and/or the y-axis.

In one aspect, the pad structure 200 may be configured to reduce damage to the at least one EE portion 208 such as sidewall cracks that may result in a degraded device life and/or deterioration in semiconductor performance. In one aspect, the pad structure 200 may be configured to reduce a degraded device life and/or deterioration in semiconductor performance. In one aspect, the pad structure 200 may be configured to reduce damage during manufacturing to the at least one EE portion 208 such as sidewall cracks that may result in a degraded device life and/or deterioration in semiconductor performance. In one aspect, the supplemental pad 202 having a zero-metal overlay as illustrated in FIG. 5 where d1 is approximately 0, can be implemented without additional photo-lithography processes, processes implemented photo-lithographic masks, and the like, for the formation of the supplemental pad 202 as it may not extend over the at least one EE portion 208.

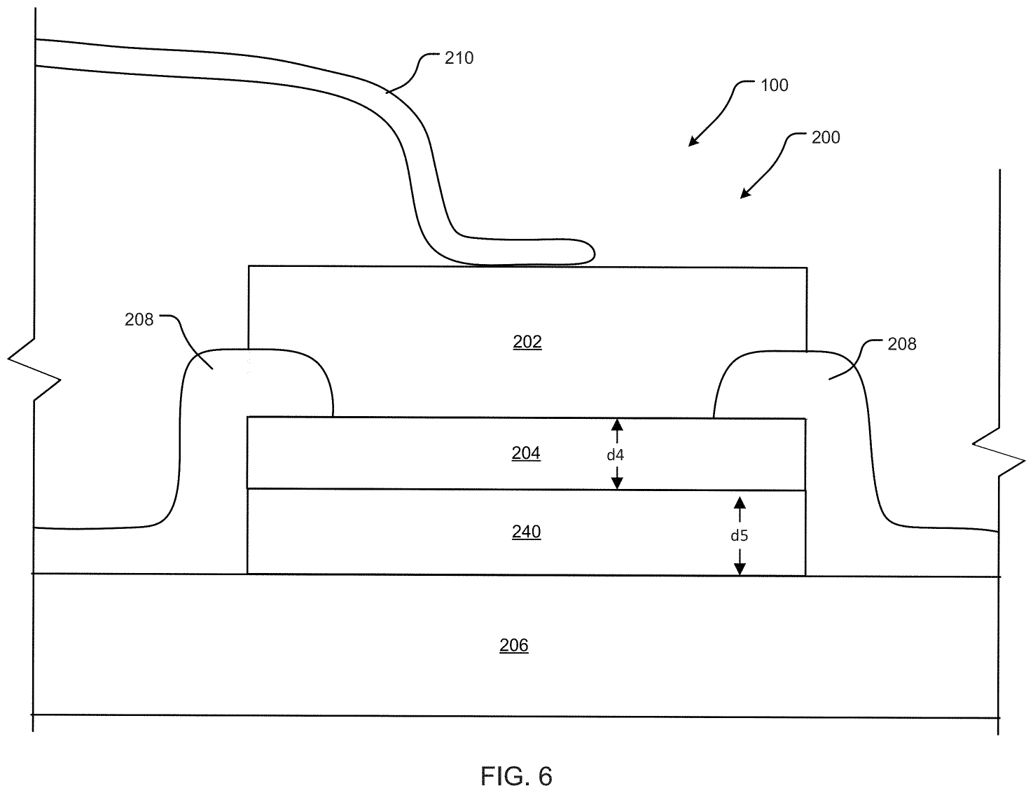

FIG. 6 shows a cross-sectional view of a pad structure for a device according to another aspect of the disclosure.

In particular, FIG. 6 illustrates the pad structure 200 which may include any one or more of the features as described herein. FIG. 6 further illustrates that the pad structure 200 may include the pad 204 and may further include a secondary pad 240. In one aspect, the secondary pad 240 may be formed from a metal such as aluminum (Al), gold (Au), silver (Ag), platinum (Pt), titanium (Ti), silicon (Si), nickel (Ni), copper (Cu), combinations thereof, and/or the like. Additionally, the secondary pad 240 may be formed of multiple layers and/or one or more overlayers of metal such as aluminum (Al), gold (Au), silver (Ag), platinum (Pt), titanium (Ti), silicon (Si), nickel (Ni), copper (Cu), combinations thereof, and/or the like. In one aspect, the material of the secondary pad 240 may be the same as the material of the pad 204. In one aspect, the material of the secondary pad 240 and the material of the pad 204 may be different. In one aspect, the material of the secondary pad 240 may be the same as the material of the supplemental pad 202. In one aspect, the material of the secondary pad 240 and the material of the supplemental pad 202 may be different.

As illustrated in FIG. 6, the secondary pad 240 may be arranged below the pad 204 and the secondary pad 240 may be arranged on the semiconductor body portion 206. The secondary pad 240 may be arranged and configured to provide additional mechanical support to address the various stresses and forces described herein. Additionally, the secondary pad 240 may be arranged and configured to provide additional mechanical support to address the various stresses and forces associated with any backside processing of the device 100. In this regard, the combined construction of the pad 204 and the secondary pad 240 may be configured to further absorb and/or release stress associated with the forces applied to the secondary pad 202 as illustrated in FIG. 3. Alternatively, a reverse construction is contemplated as well where the secondary pad 240 may be arranged above the pad 204 and the pad 204 may be arranged on the semiconductor body portion 206 (not shown).

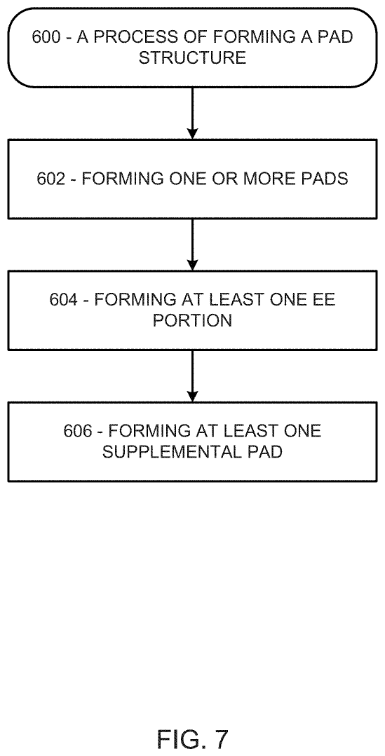

FIG. 7 shows a process of making a pad structure according to the disclosure.

In particular, FIG. 7 illustrates a process of forming a pad structure 600 that relates to the pad structure 200 as described herein. It should be noted that the aspects of the process of forming a pad structure 600 may be performed in a different order consistent with the aspects described herein. Additionally, it should be noted that portions of the process of forming a pad structure 600 may be performed in a different order consistent with the aspects described herein. Moreover, the process of forming a pad structure 600 may be modified to have more or fewer processes consistent with the various aspects disclosed herein.

Initially, the process of forming a pad structure 600 may include a process of forming the semiconductor body portion 206. Alternatively, a separate process may be utilized for forming the semiconductor body portion 206. In this regard, forming the semiconductor body portion 206 may include forming virtually any type of device, semiconductor device, and the like. In aspects, forming the semiconductor body portion 206 may include forming a transistor, forming a power device, forming a diode, forming a light-emitting diode, and/or the like. In this regard, forming a transistor may include but is not limited to forming a Metal Semiconductor Field-Effect Transistor (MESFET), forming a Metal Oxide Field Effect Transistor (MOSFET), forming a Junction Field Effect Transistor (JFET), forming a Bipolar Junction Transistor (BJT), forming an Insulated Gate Bipolar Transistor (IGBT), forming a high-electron-mobility transistor (HEMT), forming a Wide Band Gap (WBG) semiconductor, and the like. Additionally, forming a diode may include but is not limited to forming a Schottky diode, forming a non-Schottky-type diode, and/or the like.

The process of forming a pad structure 600 may include forming one or more pads 602. In particular, the pad 204 may be formed on the semiconductor body portion 206. More specifically, the pad 204 may be constructed, configured, and/or arranged as described herein on the semiconductor body portion 206.

In aspects consistent with FIG. 6, the secondary pad 240 may be formed on the semiconductor body portion 206. More specifically, the secondary pad 240 may be constructed, configured, and/or arranged as described herein on the semiconductor body portion 206. Thereafter, the pad 204 may be formed on the secondary pad 240. More specifically, the pad 204 may be constructed, configured, and/or arranged as described herein on the secondary pad 240.

Further, the process of forming a pad structure 600 may include forming at least one EE portion 604 as illustrated in FIG. 7. More specifically, the at least one EE portion 208 may be constructed, configured, and/or arranged as described herein on at least a portion of the semiconductor body portion 206 and at least a portion of the pad 204.

In aspects consistent with FIG. 6, the at least one EE portion 208 may be constructed, configured, and/or arranged as described herein on at least a portion of the secondary pad 240.

In one aspect, the at least one EE portion 208 may be modified to include the end portions 228 such that a portion of the top surface 224 of the pad 204 is exposed for a formation of the supplemental pad 202. In one aspect, the at least one EE portion 208 may be etched utilizing an etching process such that a portion of the top surface 224 of the pad 204 is exposed for a formation of the supplemental pad 202. In one aspect, the etching process may include photo-lithography processes, processes implemented photo-lithographic masks, and the like etching processes. For example, the etching processes may include a masking material which resists etching. The masking material may be a photoresist which has been patterned using photolithography. The etching processes may include one or more of wet etching, anisotropic wet etching, plasma etching, and the like.

In one aspect, the at least one EE portion 208 may be formed to include the end portions 228 such that a portion of the top surface 224 of the pad 204 is exposed for a formation of the supplemental pad 202.

In one aspect, the etching process may include a plurality of etching processes to etch each layer of the at least one EE portion 208. In one aspect, the etching process may include a plurality of etching processes to etch each layer of the at least one EE portion 208 including the encapsulation layer.

In one aspect, the etching process may simultaneously etch each layer of the at least one EE portion 208 including the encapsulation layer. In one aspect, the etching process may simultaneously etch each layer of the at least one EE portion 208.

Additionally, the process of forming a pad structure 600 may include forming at least one of a supplemental pad 606. More specifically, the supplemental pad 202 may be constructed, configured, and/or arranged as described herein on the pad 204.

In aspects consistent with FIG. 4 where d1 is greater than 0, the formation of the supplemental pad 202 may need additional photo-lithography processes, processes implemented photo-lithographic masks, and the like, for the formation of the supplemental pad 202 to extend over the at least one EE portion 208.

In aspects consistent with FIG. 5 where d1 is approximately 0, the formation of the supplemental pad 202 may avoid additional photo-lithography processes, processes implemented photo-lithographic masks, and the like, for the formation of the supplemental pad 202 as it may not extend over the at least one EE portion 208.

Once the supplemental pad 202 is formed, the bonding wires 210 may be attached to the top surface 224 of the supplemental pad 202. In this regard, the bonding wires 210 may be soldered or otherwise connected to the top surface 224 of the supplemental pad 202. As previously noted, attaching the bonding wires 210 may include application of a force such as a sonicated force.

With reference to FIGS. 1-7, the pad structure 200, the process of forming a pad structure 600, and the various concepts associated with the pad structure 200 as disclosed herein may be utilized with various semiconductor devices as illustrated by the semiconductor body portion 206. However, the pad structure 200, the process of forming a pad structure 600, and the various concepts associated with the pad structure 200 are applicable to virtually any type of device, semiconductor device, and the like. In aspects, the semiconductor body portion 206 may be implemented as a transistor, power device, a diode, a light-emitting diode, and/or the like. In this regard, the transistor types may include but are not limited to a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, and the like. The term power device may refer to various forms of transistors and diodes designed for high voltages and currents. In this regard, the diode types may include but are not limited to a Schottky diode that may be formed on a silicon carbide (SiC) substrate, a non-Schottky-type diode, and/or the like.

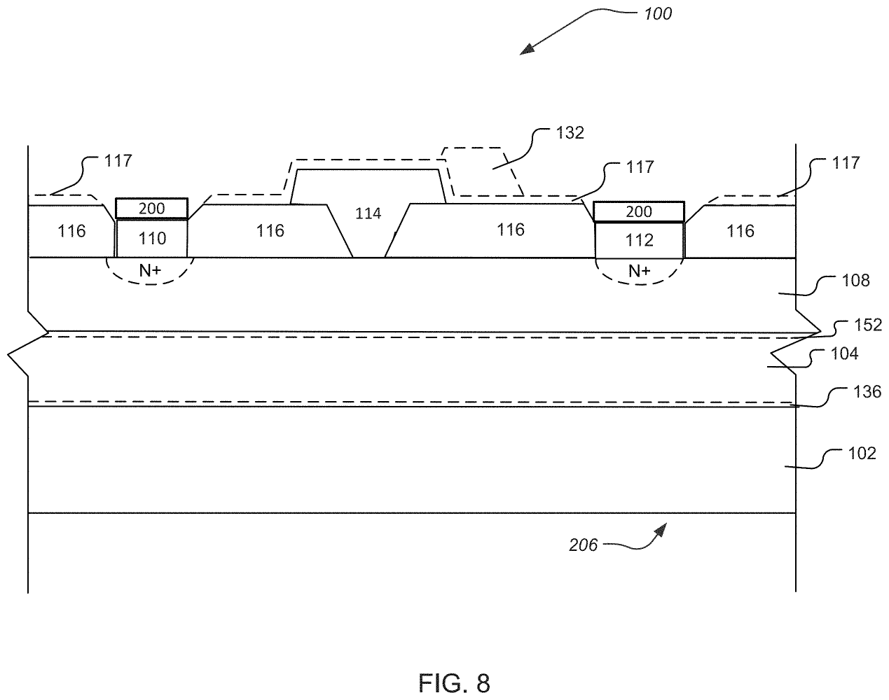

FIG. 8 shows a cross-sectional view of one aspect of a transistor implementing a pad structure according to the disclosure.

In particular, FIG. 8 shows a cross-sectional view of a transistor 100. The transistor 100 may include a source 110, a gate 114, and a drain 112. Each of the source 110, the gate 114, and the drain 112 may include or form a pad portion. Additionally, the transistor 100 may further include other pad portions. Additionally, one or more of the pad portions, for example associated with the source 110, the gate 114, and the drain 112 may include the pad structure 200 as described herein. In this regard, FIG. 8 illustrates the pad structure 200 formed on both the source 110 and the drain 112. However, any one or more of the pad portions of the transistor 100 may include the pad structure 200.

To protect and separate the gate 114 and the drain 112, a passivation layer 116 may be arranged on the transistor 100. The gate 114 may be formed of platinum (Pt), nickel (Ni), and/or gold (Au). However, other metals known to one skilled in the art to achieve the Schottky effect, may be used. In one aspect, the gate 114 may include a Schottky gate contact that may have a three layer structure. Such a structure may have advantages because of the high adhesion of some materials. In one aspect, the gate 114 may further include an overlayer of highly conductive metal. In one aspect, the gate 114 may be configured as a T-shaped gate. In one aspect, the gate 114 may be configured as a non-T-shaped gate.

Semiconductor devices such as Group III-nitride based high-electron mobility transistors (HEMTs) are very promising candidates for high power amplifiers, radiofrequency (RF) applications, and also for low frequency high power switching applications since the material properties of Group III-nitrides, such as gallium nitride (GaN) and its alloys enable achievement of high voltage and high current along with high RF gain and linearity for RF applications. A typical Group III-nitride HEMT comprises a substrate, a Group III-nitride (e.g., GaN) buffer or channel layer formed on the substrate, and a higher band-gap Group III-nitride (e.g., AlGaN) layer formed on the buffer or channel layer. Respective source, drain, and gate contacts are electrically coupled to the barrier layer. The HEMT relies on a two-dimensional electron gas (2DEG) formed at an interface between the higher band-gap barrier layer and the lower bandgap buffer or channel layer, where the lower bandgap material has a higher electron affinity. The 2DEG is an accumulation layer in the lower bandgap material and can contain a high electron concentration and high electron mobility.

The disclosure includes both extrinsic and intrinsic semiconductors. Intrinsic semiconductors are undoped (pure). Extrinsic semiconductors are doped, meaning an agent has been introduced to change the electron and hole carrier concentration of the semiconductor at thermal equilibrium. Both p-type and n-type semiconductors are disclosed, with p-types having a larger hole concentration than electron concentration, and n-types having a larger electron concentration than hole concentration.

Silicon carbide (SiC) has excellent physical and electronic properties, which should theoretically allow production of electronic devices that can operate at higher temperatures, higher power, and higher frequency than devices produced from silicon (Si) or gallium arsenide (GaAs). The high electric breakdown field of about 4×Σ6 V/cm (volts per centimeter), high saturated electron drift velocity of about 2.0×E7 cm/sec and high thermal conductivity of about 4.9 W/cm-° K indicate that SiC would be suitable for high frequency and high power applications.

As used herein, the term “Group III-nitride” refers to those semiconducting compounds formed between nitrogen and one or more elements in Group III of the periodic table, usually aluminum (Al), gallium (Ga), and indium (In). The term also refers to binary, ternary, and quaternary compounds such as GaN, AlGaN, and AlInGaN. The Group III elements can combine with nitrogen to form binary (e.g., GaN), ternary (e.g., AlGaN), and quaternary (e.g., AlInGaN) compounds. These compounds may have empirical formulas in which one mole of nitrogen is combined with a total of one mole of the Group III elements. Accordingly, formulas such as AlxGa1-xN where 1>x>0 are often used to describe these compounds.

Semiconductors, such as Group III-nitride HEMTs need the improvement of a thermal budget that limits tolerable operational temperatures due to increases in leakage current. Increases in leakage current may lead to reducing device life that may be based on in part on DC stress, RF stress, and like.

With further reference to FIG. 8, the transistor 100 may be implemented as a HEMT and may include a substrate layer 102 and a buffer layer 104. The transistor 100 may further include a barrier layer 108 arranged on the buffer layer 104. In one aspect, the barrier layer 108 may be arranged directly on the buffer layer 104.

In one aspect, a bandgap of the buffer layer 104 may be less than a bandgap of the barrier layer 108 to form a two-dimensional electron gas (2DEG) at a heterointerface 152 between the buffer layer 104 and barrier layer 108 when biased at an appropriate level. In one aspect, the buffer layer 104 is a Group III-nitride material, such as GaN, and the barrier layer 108 is a Group III-nitride material, such as AlGaN or AlN. In some aspects, there may be intervening layer(s) or region(s) between the substrate layer 102 and the buffer layer 104, such as a nucleation layer 136. In one aspect, there may be intervening layer(s) or region(s) (not shown) between the buffer layer 104 and the barrier layer 108. In one aspect, the barrier layer 108 is made of multiple layers, such as an AlN barrier layer on the buffer layer 104, and an AlGaN layer on the AlN barrier layer. In one aspect, there are intervening layer(s) or region(s) between the barrier layer 108 and a passivation layer 116 and/or the source 110, the gate 114 and/or the drain 112. In one aspect, the composition of these layers can be step-wise or continuously graded. In one aspect, the barrier layer 108 can start with a higher percentage of Al near the buffer layer 104 and decrease in Al percentage away from the buffer layer 104.

In aspects of the transistor 100 of the disclosure, a gate contact may be provided for the gate 114 in between the source 110 and the drain 112. Furthermore, in certain aspects of the disclosure, the gate contact may be disposed on the barrier layer 108. In one aspect, the gate contact may be disposed directly on the barrier layer 108.

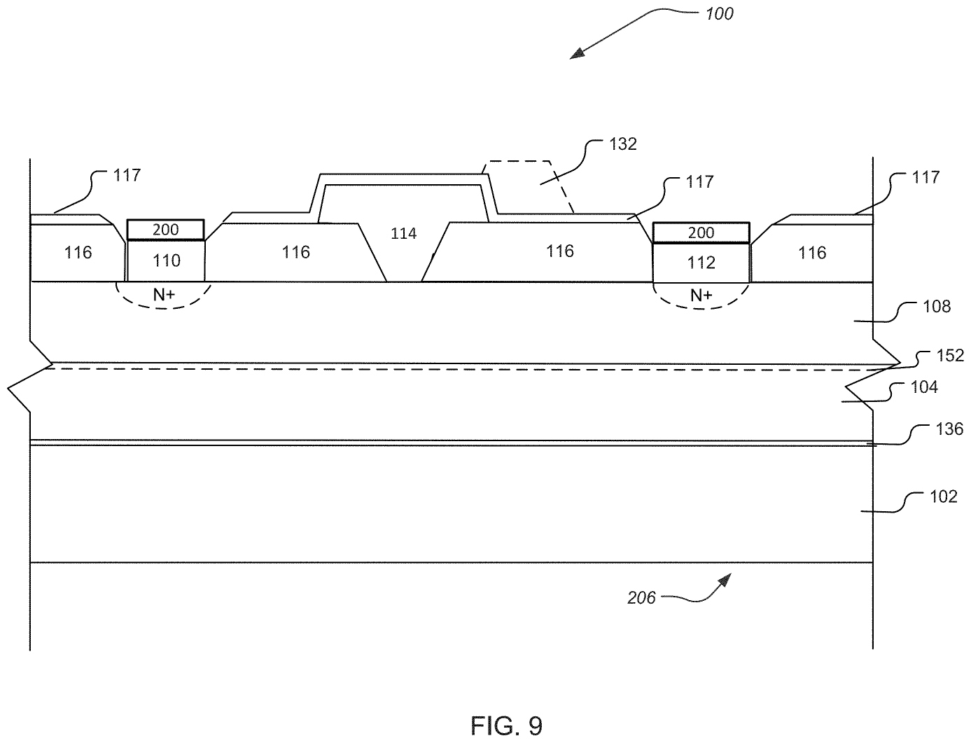

FIG. 9 shows a cross-sectional view of one aspect of a transistor implementing a pad structure according to the disclosure.

In particular, FIG. 9 is a transistor 100 that may include any one or more of the features of the disclosure. In one aspect, the transistor 100 of FIG. 9 may include one or more of the features of the disclosure illustrated in FIG. 1, FIG. 2, FIG. 3, FIG. 4, FIG. 5, and/or FIG. 6 and the description thereof. FIG. 9 further illustrates that the transistor 100 may include a spacer layer 117 and may include a nucleation layer 136.

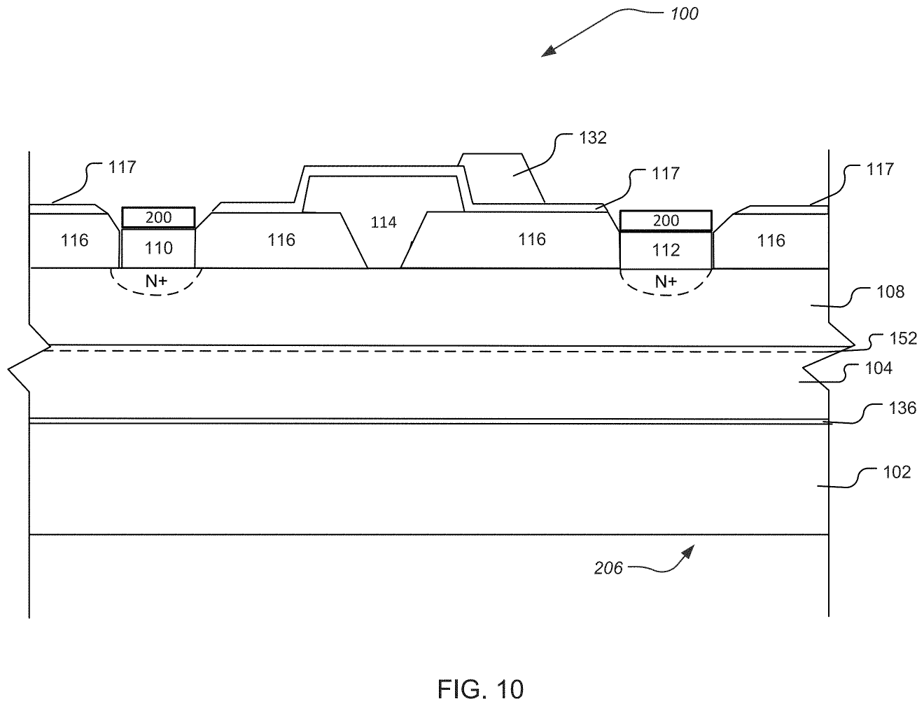

FIG. 10 shows a cross-sectional view of one aspect of a transistor implementing a pad structure according to the disclosure.

In particular, FIG. 10 is a transistor 100 that may include any one or more of the features of the disclosure. In one aspect, the transistor 100 of FIG. 10 may include one or more of the features of the disclosure illustrated in FIG. 1, FIG. 2, FIG. 3, FIG. 4, FIG. 5, and/or FIG. 6 and the description thereof. FIG. 10 further illustrates that the transistor 100 may include a spacer layer 117, a field plate 132, and a nucleation layer 136. In one aspect, a plurality of the field plates 132 may be used and each of the plurality of field plates 132 may be stacked with a dielectric material therebetween (not shown).

In aspects of the transistor 100 of the disclosure, the substrate layer 102 may be made of Silicon Carbide (SiC) or sapphire. In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. In one aspect, the substrate layer 102 may be formed of SiC selected from the group of 6H, 4H, 15R, 3C SiC, or the like. In another aspect, the substrate layer 102 may be GaAs, GaN, or other material suitable for the applications described herein. In another aspect, the substrate layer 102 may include sapphire, spinel, ZnO, silicon, or any other material capable of supporting growth of Group III-nitride materials.

On the substrate layer 102, a buffer layer 104, and/or a nucleation layer 136, may be formed. In one aspect, the buffer layer 104 is formed on the substrate layer 102. In one aspect, the buffer layer 104 is formed directly on the substrate layer 102. In one aspect, the nucleation layer 136 may be formed on the substrate layer 102. In one aspect, the nucleation layer 136 may be formed directly on the substrate layer 102. Intervening layer(s) and/or region(s) are possible throughout the described structures.

In aspects of the transistor 100 of the disclosure, the nucleation layer 136 may be formed on the substrate layer 102 to reduce a lattice mismatch between the substrate layer 102 and a next layer in the transistor 100. The nucleation layer 136 may include many different materials, such as Group III-nitride materials, with a suitable material being Al_{z}Ga_{1-z}N (0<=z<=1). The nucleation layer 136 may be formed on the substrate layer 102 using known semiconductor growth techniques such as Metal Oxide Chemical Vapor Deposition (MOCVD), Hydride Vapor Phase Epitaxy (HVPE), Molecular Beam Epitaxy (MBE), or the like. In further aspects, there may be intervening layers between the nucleation layer 136 and the substrate layer 102. In further aspects, there may be intervening layers between the nucleation layer 136 and the buffer layer 104.

The buffer layer 104 may be a group III-nitride, such as GaN, Aluminum Gallium Nitride (AlGaN), Aluminum Nitride (AlN), AlₓGa_{y}In_{(1-x-y)}N (where 0<=x<=1, 0<=y<=1, x+y<=1), AlₓIn_{y}Ga_{1-x-y}N (where 0<=x<=1 and 0<=y<=1), and the like, or another suitable material and may also include a nucleation layer 136 of a group III-nitride material, such as AlN. In one aspect, the buffer layer 104 is formed of AlGaN. The buffer layer 104 may be a p-type material, or alternatively can be undoped. In one aspect, an AlN nucleation layer 136 may be used to adhere to the substrate layer 102 and may help grow the buffer layer 104. The buffer layer 104 may bind to the substrate layer 102. In one aspect, the nucleation layer 136 may be AlGaN.

In one aspect, the buffer layer 104 may be high purity GaN. In one aspect, the buffer layer 104 may be high purity GaN that may be a low-doped n-type. In one aspect, the buffer layer 104 may also use a higher band gap Group III-nitride layer as a back barrier, such as an AlGaN back barrier, on the other side of the buffer layer 104 from the barrier layer 108 to achieve better electron confinement.

In aspects of the transistor 100 of the disclosure, on the buffer layer 104, the barrier layer 108 may be formed. In one aspect, the barrier layer 108 may be formed directly on the buffer layer 104. The barrier layer 108 may provide an additional layer between the buffer layer 104 and the source 110, the drain 112, and the gate 114. The barrier layer 108 may be AlGaN, AlN, a Group III-nitride, InAlGaN, or another suitable material. In one aspect, the barrier layer 108 may be AlGaN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, a bandgap of the buffer layer 104 may be less than a bandgap of the barrier layer 108. In one aspect, a bandgap of the buffer layer 104 may be less than a bandgap of the barrier layer 108 to form a two-dimensional electron gas (2DEG) at a heterointerface 152 between the buffer layer 104 and barrier layer 108 when biased at an appropriate level. In one aspect, additional Group III-nitride layer(s) or region(s) and/or other layer(s) or region(s) of different materials are possible on the barrier layer 108 and/or in the overall structure. Any of the layers and/or regions can have uniform, non-uniform, graded and/or changing composition, thicknesses, and/or doping.

In aspects of the transistor 100 of the disclosure, the source 110 and/or the drain 112 may be connected directly to the barrier layer 108. In one aspect, the source 110 and/or drain 112 may be connected indirectly to the barrier layer 108. In one aspect, the barrier layer 108 may include a region under the source 110 and/or drain 112 that is an N+ material. In one aspect, the barrier layer 108 may include a region under the source 110 and/or drain 112 that is Si doped.

In aspects of the transistor 100 of the disclosure, the source 110 and/or the drain 112 may be connected directly to the buffer layer 104. In one aspect, the source 110 and/or drain 112 may be connected indirectly to the buffer layer 104. In one aspect, the buffer layer 104 may include a region under the source 110 and/or drain 112 that is an N+ material. In one aspect, the buffer layer 104 may include a region under the source 110 and/or drain 112 that is Si doped.

To protect and separate the gate 114 and the drain 112, the passivation layer 116 may be arranged on the barrier layer 108, on a side opposite the buffer layer 104, adjacent the gate 114 and the drain 112. The passivation layer 116 may be a passivation layer made of SiN, AlO, SiO, SiO₂, AlN, or the like, or a combination incorporating multiple layers thereof. In one aspect, the passivation layer 116 is a passivation layer made of SiN. In one aspect, the passivation layer 116 can be deposited using MOCVD, plasma chemical vapor deposition (CVD), hot-filament CVD, or sputtering. In one aspect, the passivation layer 116 may include deposition of Si₃N₄. In one aspect, the passivation layer 116 forms an insulating layer. In one aspect, the passivation layer 116 forms an insulator. In one aspect, the passivation layer 116 may be a dielectric.

In aspects of the transistor 100 of the disclosure, a non-conducting spacer layer 117 may be formed over the gate 114 between the source 110 and the drain 112. In one aspect, the spacer layer 117 may include a layer of non-conducting material such as a dielectric. In one aspect, the spacer layer 117 may include a number of different layers of dielectrics or a combination of dielectric layers. In one aspect, the spacer layer 117 may be many different thicknesses, with a suitable range of thicknesses being approximately 0.5 to 2 microns.

In one aspect, the spacer layer 117 may include a material such as a dielectric or insulating material, such as SiN, SiO₂, etc. In some aspects, the spacer layer 117 may be a passivation layer, such as SiN, AlO, SiO, SiO₂, AlN, or the like, or a combination incorporating multiple layers thereof

In aspects of the transistor 100 of the disclosure, the buffer layer 104 may be designed to be of the high purity type where the Fermi level is in the upper half of the bandgap, which minimizes slow trapping effects normally observed in GaN HEMTs. In this regard, the traps under the Fermi level are filled always and thus slow transients may be prevented. In some aspects, the buffer layer 104 may be as thin as possible consistent with achieving good crystalline quality. Applicants have already demonstrated 0.4 μm layers with good quality.

In aspects of the transistor 100 of the disclosure, a Group III-nitride nucleation layer 136 and/or buffer layer 104 may be grown on the substrate layer 102 via an epitaxial crystal growth method, such as MOCVD (Metalorganic Chemical Vapor Deposition), HVPE (Hydride Vapor Phase Epitaxy) or MBE (Molecular Beam Epitaxy). The formation of the nucleation layer 136 may depend on the material of the substrate layer 102.

In aspects of the transistor 100 of the disclosure, the buffer layer 104 may be formed with Lateral Epitaxial Overgrowth (LEO). LEO can, for example, improve the crystalline quality of GaN layers. When semiconductor layers of a HEMT are epitaxial, the layer upon which each epitaxial layer is grown may affect the characteristics of the device. For example, LEO may reduce dislocation density in epitaxial GaN layers.

In aspects of the transistor 100 of the disclosure, the buffer layer 104 may include nonpolar GaN. In one aspect, the buffer layer 104 may include semipolar GaN. In one aspect, the buffer layer 104 may include hot wall epitaxy. In one aspect, the buffer layer 104 may include hot wall epitaxy having a thickness in the range of 0.15 microns to 0.25 microns, 0.2 microns to 0.3 microns, 0.25 microns to 0.35 microns, 0.3 microns to 0.35 microns, 0.35 microns to 0.4 microns, 0.4 microns to 0.45 microns, 0.45 microns to 0.5 microns, 0.5 microns to 0.55 microns, or 0.15 microns to 0.55 microns.

In aspects of the transistor 100 of the disclosure, one or more metal overlayers may be provided on one or more of the source 110, the drain 112, and the gate 114. The overlayers may be Au, Ag, Al, Pt, Ti, Si, Ni, Al, and/or Cu. Other suitable highly conductive metals may also be used for the overlayers.

In one aspect, the field plate 132 may be arranged on the spacer layer 117 between the gate 114 and drain 112. In one aspect, the field plate 132 may be deposited on the spacer layer 117 between the gate 114 and the drain 112. In some aspects, the field plate 132 may be adjacent the gate 114 and an additional spacer layer 117 of dielectric material may be included at least partially over the gate 114 to isolate the gate 114 from the field plate 132 (not shown). In some aspects, the field plate 132 may overlap the gate 114 and an additional spacer layer 117 of dielectric material may be included at least partially over the gate 114 to isolate the gate 114 from the field plate 132.

The field plate 132 may extend different distances from the edge of the gate 114, with a suitable range of distances being approximately 0.1 to 2 microns. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like.

In one aspect, the field plate 132 may be formed on the spacer layer 117 between the gate 114 and the drain 112, with the field plate 132 being in proximity to the gate 114 but not overlapping the gate 114. In one aspect, a space between the gate 114 and field plate 132 may be wide enough to isolate the gate 114 from the field plate 132, while being small enough to maximize a field effect provided by the field plate 132.

In certain aspects, the field plate 132 may reduce a peak operating electric field in the transistor 100. In certain aspects, the field plate 132 may reduce the peak operating electric field in the transistor 100 and may increase the breakdown voltage of the transistor 100. In certain aspects, the field plate 132 may reduce the peak operating electric field in the transistor 100 and may reduce trapping in the transistor 100. In certain aspects, the field plate 132 may reduce the peak operating electric field in the transistor 100 and may reduce leakage currents in the transistor 100.

In aspects of the transistor 100 of the disclosure, the source 110 and the drain 112 may be symmetrical with respect to the gate 114. In some device application aspects, the source 110 and the drain 112 may be asymmetrical with respect to the gate 114.

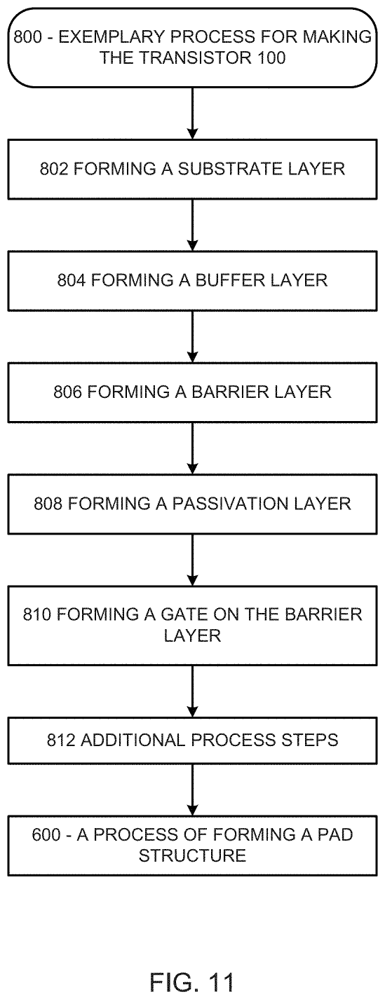

FIG. 11 shows a process of making a transistor according to the disclosure.

In particular, FIG. 11 shows an exemplary process 800 for making the transistor 100 of the disclosure. It should be noted that the process 800 is merely exemplary and may be modified consistent with the various aspects disclosed herein.

The process 800 may begin at box 802 by forming a substrate layer 102. The substrate layer 102 may be made of Silicon Carbide (SiC). In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. The substrate layer 102 may be formed of SiC selected from the group of 6H, 4H, 15R, 3C SiC, or the like. In another aspect, the substrate layer 102 may be GaAs, GaN, or other material suitable for the applications described herein. In another aspect, the substrate layer 102 may include spinel, ZnO, silicon, or any other material capable of supporting growth of Group III-nitride materials. Additionally, the above-noted process may include any other aspects consistent with the disclosure.

The buffer layer 104 may be formed at box 804 on the substrate layer 102. The buffer layer 104 may be grown or deposited on the substrate layer 102. In one aspect, the buffer layer 104 may be GaN. In another aspect, the buffer layer 104 may be formed with LEO. In one aspect, the nucleation layer 136 may be formed on the substrate layer 102 and the buffer layer 104 may be formed on the nucleation layer 136. The buffer layer 104 may be grown or deposited on the nucleation layer 136. In one aspect, the buffer layer 104 may be GaN. In another aspect, the buffer layer 104 may be formed with LEO. Additionally, the above-noted process may include any other aspects consistent with the disclosure.

At box 806, the barrier layer 108 may be formed on the buffer layer 104. The barrier layer 108 may be an n-type conductivity layer or may be undoped. In one aspect, the barrier layer 108 may be AlGaN. In one aspect, the barrier layer 108 may be formed directly on the buffer layer 104. The barrier layer 108 may provide an additional layer between the buffer layer 104 and the source 110, the drain 112, and the gate 114. The barrier layer 108 may be AlGaN, AlN, a Group III-nitride, InAlGaN, or another suitable material. In one aspect, the barrier layer 108 may be AlGaN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, a bandgap of the buffer layer 104 may be less than a bandgap of the barrier layer 108. In one aspect, a bandgap of the buffer layer 104 may be less than a bandgap of the barrier layer 108 to form a two-dimensional electron gas (2DEG) at a heterointerface 152 between the buffer layer 104 and barrier layer 108 when biased at an appropriate level. In one aspect, additional Group III-nitride layer(s) or region(s) and/or other layer(s) or region(s) of different materials are possible on the barrier layer 108 and/or in the overall structure. Any of the layers and/or regions can have uniform, non-uniform, graded and/or changing composition, thicknesses, and/or doping. Additionally, the above-noted process may include any other aspects consistent with the disclosure.

At box 808, the passivation layer 116 may be formed. The passivation layer 116 may be a passivation layer, such as SiN, AlO, SiO, SiO₂, AlN, or the like, or a combination incorporating multiple layers thereof, which may be deposited over the exposed surface of the barrier layer 108. Additionally, the above-noted process may include any other aspects consistent with the disclosure.

At box 810, the gate 114 may be arranged on the barrier layer 108 between the source 110 and the drain 112. The gate 114 may extend on top of a spacer or the passivation layer 116. The passivation layer 116 may be etched and the gate 114 deposited such that the bottom of the gate 114 is on and/or adjacent the surface of barrier layer 108. The metal forming the gate 114 may be patterned to extend across passivation layer 116 so that the top of the gate 114 forms a field plate 132.

A layer of Ni, Pt, AU, or the like may be formed for the gate 114 by evaporative deposition or another technique. The gate structure may then be completed by deposition of Pt and Au, or other suitable materials. In some aspects, the contacts of the gate 114 may include Al, Ti, Si, Ni, and/or Pt.

Further during the process 800, additional processes 812 may be performed. For example, the source 110 may be arranged on the barrier layer 108. The source 110 may be an ohmic contact of a suitable material that may be annealed. For example, the source 110 may be annealed at a temperature of from about 500° C. to about 800° C. for about 2 minutes. However, other times and temperatures may also be utilized. Times from about 30 seconds to about 10 minutes may be, for example, acceptable. In some aspects, the source 110 may include Al, Ti, Si, Ni, and/or Pt. In one aspect, a region under the source 110 that is an N+ material may be formed in the barrier layer 108. In one aspect, a region under the drain 112 may be Si doped.

Further during the additional processes 812, the drain 112 may be arranged on the barrier layer 108. Like the source 110, the drain 112 may be an ohmic contact of Ni or another suitable material, and may also be annealed in a similar fashion. In one aspect, an n+ implant may be used in conjunction with the barrier layer 108 and the contacts are made to the implant. In one aspect, a region under the drain 112 that is an N+ material may be formed in the barrier layer 108. In one aspect, a region under the drain 112 may be Si doped.

The source 110 and the drain 112 electrodes may be formed making ohmic contacts such that an electric current flows between the source 110 and drain 112 electrodes via a two-dimensional electron gas (2DEG) induced at the heterointerface 152 between the buffer layer 104 and barrier layer 108 when a gate 114 electrode is biased at an appropriate level. In one aspect, the heterointerface 152 may be in the range of 0.005 μm to 0.007 μm, 0.007 μm to 0.009 μm, and 0.009 μm to 0.11 μm.

Further during some aspects of the additional processes 812, the field plate 132 may be arranged on top of another protective layer and may be separated from the gate 114. In one aspect, the field plate 132 may be deposited on the spacer layer 117 between the gate 114 and the drain 112. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like. In one aspect, a plurality of the field plates 132 may be used. In one aspect, a plurality of the field plates 132 may be used and each of the plurality of field plates 132 may be stacked with a dielectric material therebetween. In one aspect, the field plate 132 extends toward the edge of gate 114 towards the drain 112. In one aspect, the field plate 132 extends towards the source 110. In one aspect, the field plate 132 extends towards the drain 112 and towards the source 110. In another aspect, the field plate 132 does not extend toward the edge of gate 114. Finally, the structure may be covered with a dielectric spacer layer 117 such as silicon nitride. The dielectric spacer layer 117 may also be implemented similar to the passivation layer 116. Moreover, it should be noted that the cross-sectional shape of the gate 114, shown in the Figures is exemplary. For example, the cross-sectional shape of the gate 114 in some aspects may not include the T-shaped extensions. Other constructions of the gate 114 may be utilized. Additionally, the above-noted process may include any other aspects consistent with the disclosure.

Further during the process 800, the process of forming a pad structure 600 may be performed that relates to the pad structure 200 as described herein. As noted above, the process of forming a pad structure 600 may include one or more of forming one or more pads 602; forming at least one EE portion 604; and/or forming at least one of a supplemental pad 606. Once the supplemental pad 202 is formed, the bonding wires 210 may be attached to the top surface 224 of the supplemental pad 202.

It should be noted that the aspects of process 800 may be performed in a different order consistent with the aspects described above. Additionally, it should be noted that portions of the process 800 may be performed in a different order consistent with the aspects described above. Moreover, the process 800 may be modified to have more or fewer processes consistent with the various aspects disclosed herein.

Accordingly, the disclosure has provided processes and devices for die pads and semiconductors having die pads having improved environmental protection to address extreme temperature ranges, humidity ranges, and/or a host of other environmental conditions. Moreover, the disclosure has provided processes and devices for die pads and semiconductors having die pads having improved environmental protection to address operation at or near rated currents and voltages over extended periods of time. Additionally, the disclosure has provided processes and devices for die pads and semiconductors having die pads having improved environmental protection to address manufacturing issues such as insufficiently optimized wire bonding processes as well as others. Moreover, the disclosure has provided processes and devices for die pads and semiconductors having die pads to reduce damage to the at least one EE portion 208 such as sidewall cracks that may result in a degraded device life and/or deterioration in semiconductor performance. Additionally, the disclosure has provided processes and devices for die pads and semiconductors having die pads to reduce a degraded device life and/or deterioration in semiconductor performance.

In particular aspects, the transistor 100 of the disclosure may be utilized in radio frequency (RF) applications. In further aspects, the transistor 100 of the disclosure may be utilized in wireless base stations that connect to a wireless device. In further aspects, the transistor 100 of the disclosure may be utilized in in wireless devices.

In this disclosure it is to be understood that reference to a wireless device is intended to encompass electronic devices such as mobile phones, tablet computers, gaming systems, MP3 players, personal computers, PDAs, user equipment (UE), and the like. A “wireless device” is intended to encompass any compatible mobile technology computing device that can connect to a wireless communication network, such as mobile phones, mobile equipment, mobile stations, user equipment, cellular phones, smartphones, handsets, wireless dongles, remote alert devices, Internet of things (IoT) based wireless devices, or other mobile computing devices that may be supported by a wireless network. The wireless device may utilize wireless communication technologies like GSM, CDMA, wireless local loop, W-Fi, WMAX, other wide area network (WAN) technology, 3G technology, 4G technology, 5G technology, LTE technology, and the like.

In this disclosure it is to be understood that reference to a wireless base station is intended to cover base transceiver station (BTS), node B devices, Base Station (BS) devices, evolved node B devices, and the like that facilitate wireless communication between wireless devices and a network. The wireless base station and/or the network may utilize wireless communication technologies like GSM, CDMA, wireless local loop, Wi-Fi, WiMAX, other wide area network (WAN) technology, 3G technology, 4G technology, 5G technology, LTE technology, and the like.

In particular aspects, the transistor 100 of the disclosure may be utilized in power semiconductor devices. In one aspect, the power semiconductor devices may be utilized for a power module that may include structure optimized for state-of-the-art wide band gap power semiconductor devices such as Gallium Nitride (GaN), Silicon Carbide (SiC), and the like, which are capable of carrying high amounts of currents and voltages and switching at increasingly faster speeds in comparison with established technologies. The power devices may include Wide Band Gap (WBG) semiconductors, including Gallium Nitride (GaN), Silicon Carbide (SiC), and the like, and offer numerous advantages over conventional Silicon (Si) as a material for the power devices. Nevertheless, various aspects of the disclosure may utilize Si type power devices and achieve a number of the benefits described herein.

In aspects, the dimensions of d1, d2, d3, and/or d4, may be critical in order to address extreme temperature ranges, humidity ranges, and/or a host of other environmental conditions; operation at or near rated currents and voltages over extended periods of time; and address manufacturing issues such as insufficiently optimized wire bonding processes as well as others.

### EXAMPLES

Example 1. A device configured with a pad structure having environmental protection, the device comprising: a semiconductor body portion; a pad; at least one environment encapsulation portion; a supplemental pad; the pad being arranged on the semiconductor body portion; and the supplemental pad being arranged on the pad, wherein the supplemental pad includes side surfaces that extend vertically above the at least one environment encapsulation portion.

Example 2. The device according to any example described herein wherein the side surfaces are free of the at least one environment encapsulation portion.

Example 3. The device according to any example described herein wherein the at least one environment encapsulation portion includes end portions arranged on the pad and at least portions of the supplemental pad are arranged vertically above the end portions.

Example 4. The device according to any example described herein wherein: the at least one environment encapsulation portion includes end portions arranged on the pad; and the side surfaces of the supplemental pad are configured to extend vertically from the end portions of the at least one environment encapsulation portion.

Example 5. The device according to any example described herein wherein a top surface of the supplemental pad is arranged above the at least one environment encapsulation portion.

Example 6. The device according to any example described herein wherein the supplemental pad is configured to connect to a bonding wire.

Example 7. The device according to any example described herein wherein: the pad includes a top surface and side surfaces; and the at least one environment encapsulation portion is configured to partially contact and cover the side surfaces of the pad.

Example 8. The device according to any example described herein wherein: the at least one environment encapsulation portion is configured to partially contact and partially cover a top surface of the pad and leave a central portion of the top surface free of the at least one environment encapsulation portion; and the supplemental pad includes a bottom surface configured to contact the top surface of the pad in the central portion.

Example 9. The device according to any example described herein wherein the at least one environment encapsulation portion comprises at least one of the following: a layer that is SiN, a layer that is SiO₂, and an encapsulation layer.

Example 10. The device according to any example described herein wherein the at least one environment encapsulation portion comprises multiple layers.

Example 11. The device according to any example described herein wherein the pad structure is configured to reduce damage to the at least one environment encapsulation portion.

Example 12. The device according to any example described herein wherein the semiconductor body portion comprises a substrate, a source, a gate, and a drain.

Example 13. The device according to any example described herein wherein the semiconductor body portion comprises: a substrate; a buffer layer on the substrate; a barrier layer on the buffer layer; a passivation layer on the barrier layer a source electrically coupled to the barrier layer; a gate electrically coupled to the barrier layer; and a drain electrically coupled to the barrier layer.

Example 14. A process of forming a device with a pad structure having environmental protection, the process comprising: providing a semiconductor body portion; arranging a pad on the semiconductor body portion; providing at least one environment encapsulation portion at least partially on the pad; arranging a supplemental pad on the pad; and arranging the supplemental pad to include side surfaces that extend vertically above the at least one environment encapsulation portion.

Example 15. The process of forming a device with a pad structure having environmental protection according to any example described herein further comprising configuring the side surfaces to be free of the at least one environment encapsulation portion.

Example 16. The process of forming a device with a pad structure having environmental protection according to any example described herein further comprising configuring the at least one environment encapsulation portion to include end portions arranged on the pad and arranging at least portions of the supplemental pad vertically above the end portions.

Example 17. The process of forming a device with a pad structure having environmental protection according to any example described herein further comprising configuring the at least one environment encapsulation portion to include end portions arranged on the pad and configuring the side surfaces of the supplemental pad to extend vertically above the end portions of the at least one environment encapsulation portion.

Example 18. The process of forming a device with a pad structure having environmental protection according to any example described herein further comprising providing a top surface of the supplemental pad arranged above the at least one environment encapsulation portion.

Example 19. The process of forming a device with a pad structure having environmental protection according to any example described herein further comprising configuring the supplemental pad to connect to a bonding wire.

Example 20. The process of forming a device with a pad structure having environmental protection according to any example described herein further comprising: configuring the pad to include a top surface and side surfaces; and arranging the at least one environment encapsulation portion to partially contact and cover the side surfaces of the pad.

Example 21. The process of forming a device with a pad structure having environmental protection according to any example described herein further comprising: arranging the at least one environment encapsulation portion to at least partially contact and partially cover a top surface of the pad and etching a central portion of the top surface to be free of the at least one environment encapsulation portion; and configuring the supplemental pad to include a bottom surface to contact the top surface of the pad in the central portion.

Example 22. The process of forming a device with a pad structure having environmental protection according to any example described herein further comprising configuring the supplemental pad to include a bottom surface to contact a top surface of the pad.

Example 23. The process of forming a device with a pad structure having environmental protection according to any example described herein further comprising configuring the at least one environment encapsulation portion with at least one of the following: a layer that is SiN, a layer that is SiO₂, and an encapsulation layer.

Example 24. The process of forming a device with a pad structure having environmental protection according to any example described herein further comprising configuring the at least one environment encapsulation portion with multiple layers.

Example 25. The process of forming a device with a pad structure having environmental protection according to any example described herein further comprising configuring the pad structure to reduce damage to the at least one environment encapsulation portion.

Example 26. The process of forming a device with a pad structure having environmental protection according to any example described herein wherein the providing a semiconductor body portion further comprises: providing a substrate, a gate, a source, and a drain.

Example 27. The process of forming a device with a pad structure having environmental protection according to any example described herein wherein the providing a semiconductor body portion further comprises: providing a substrate; arranging a buffer layer on the substrate; arranging a barrier layer on the buffer layer; electrically coupling a source to the barrier layer; electrically coupling a gate to the barrier layer; electrically coupling a drain to the barrier layer; forming a passivation layer on the barrier layer; and forming a gate electrically coupled to the barrier layer.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

1. A device configured with a pad structure having environmental protection, the device comprising:
a semiconductor body portion;
a pad;
at least one environment encapsulation portion;
a supplemental pad;
the pad being arranged on the semiconductor body portion; and
the supplemental pad being arranged on the pad,
wherein the supplemental pad includes side surfaces that extend vertically above the at least one environment encapsulation portion; and
wherein the supplemental pad comprises a top surface configured to bond to a bonding wire.

2. The device according to claim 1 wherein the side surfaces are free of the at least one environment encapsulation portion.

3. The device according to claim 1 wherein the at least one environment encapsulation portion includes end portions arranged on the pad and at least portions of the supplemental pad are arranged vertically above the end portions.

4. The device according to claim 1 wherein:
the at least one environment encapsulation portion includes end portions arranged on the pad; and
the side surfaces of the supplemental pad are configured to extend vertically from the end portions of the at least one environment encapsulation portion such that the side surfaces of the supplemental pad do not overlay the end portions of the at least one environment encapsulation portion.

5. The device according to claim 1 further comprising:
a secondary pad arranged between the semiconductor body portion and the pad,
wherein a top surface of the supplemental pad is arranged above the at least one environment encapsulation portion; and
wherein the secondary pad and the pad are arranged below at least a portion of the at least one environment encapsulation portion.

6. The device according to claim 1 wherein:
the pad includes a top surface and side surfaces; and
the at least one environment encapsulation portion is configured to partially contact and cover the side surfaces of the pad.

7. The device according to claim 1 wherein:
the at least one environment encapsulation portion is configured to partially contact and partially cover a top surface of the pad and leave a central portion of the top surface free of the at least one environment encapsulation portion; and
the supplemental pad includes a bottom surface configured to contact the top surface of the pad in the central portion.

8. The device according to claim 1 wherein the at least one environment encapsulation portion comprises multiple layers.

9. The device according to claim 1 wherein the pad structure is configured to release stress and reduce damage to the at least one environment encapsulation portion during bonding of the bonding wire to the pad structure.

10. The device according to claim 1 wherein the semiconductor body portion comprises a substrate, a source, a gate, and a drain.

11. A process of forming a device with a pad structure having environmental protection, the process comprising:
providing a semiconductor body portion;
arranging a pad on the semiconductor body portion;
providing at least one environment encapsulation portion at least partially on the pad;
arranging a supplemental pad on the pad; and
arranging the supplemental pad to include side surfaces that extend vertically above the at least one environment encapsulation portion,
wherein the supplemental pad comprises a top surface configured to bond to a bonding wire.

12. The process of forming a device with a pad structure having environmental protection according to claim 11 further comprising configuring the side surfaces to be free of the at least one environment encapsulation portion.

13. The process of forming a device with a pad structure having environmental protection according to claim 11 further comprising configuring the at least one environment encapsulation portion to include end portions arranged on the pad and arranging at least portions of the supplemental pad vertically above the end portions.

14. The process of forming a device with a pad structure having environmental protection according to claim 11 further comprising configuring the at least one environment encapsulation portion to include end portions arranged on the pad and configuring the side surfaces of the supplemental pad to extend vertically above the end portions of the at least one environment encapsulation portion such that the side surfaces of the supplemental pad do not overlay the end portions of the at least one environment encapsulation portion.

15. The process of forming a device with a pad structure having environmental protection according to claim 11 further comprising:
providing a secondary pad arranged between the semiconductor body portion and the pad; and
providing a top surface of the supplemental pad arranged above the at least one environment encapsulation portion,
wherein the secondary pad and the pad are arranged below at least a portion of the at least one environment encapsulation portion.

16. The process of forming a device with a pad structure having environmental protection according to claim 11 further comprising:
configuring the pad to include a top surface and side surfaces; and
arranging the at least one environment encapsulation portion to partially contact and cover the side surfaces of the pad.

17. The process of forming a device with a pad structure having environmental protection according to claim 11 further comprising:
arranging the at least one environment encapsulation portion to at least partially contact and partially cover a top surface of the pad and etching a central portion of the top surface to be free of the at least one environment encapsulation portion; and
configuring the supplemental pad to include a bottom surface to contact the top surface of the pad in the central portion.

18. The process of forming a device with a pad structure having environmental protection according to claim 11 further comprising configuring the at least one environment encapsulation portion with multiple layers.

19. The process of forming a device with a pad structure having environmental protection according to claim 11 further comprising configuring the pad structure to release stress and reduce damage to the at least one environment encapsulation portion during bonding of the bonding wire to the pad structure.

20. The process of forming a device with a pad structure having environmental protection according to claim 11 wherein the providing a semiconductor body portion further comprises: providing a substrate, a gate, a source, and a drain.
